(19) United States
(12) Patent Application Publication
(10) Pub. No.: US 2010/0329019 A1
(43) Pub. Date: Dec. 30, 2010

(54) SEMICONDUCTOR STORAGE DEVICE AND ELECTRONIC DEVICE USING THE SAME

(75) Inventor: Toshio MUKUNOKI, Nara (JP)

Correspondence Address: MCDERMOTT WILL & EMERY LLP, 600 13TH STREET, NW, WASHINGTON, DC, 20005-3096, US

(73) Assignee: Panasonic Corporation, Osaka (JP)

(21) Appl. No.: 12/874,687

(22) Filed: Sep. 2, 2010

Related U.S. Application Data
(63) Continuation of application No. PCT/JP2008/003191, filed on Nov. 5, 2008.

(30) Foreign Application Priority Data
Apr. 28, 2008 (JP) 2008-117328

(51) Int. Cl. G11C 16/04

(52) U.S. Cl. 365/185.18

(57) ABSTRACT

When data is read from a memory cell of a top array block to a bit line, a switching device is closed so that the data is stored in the form of electrical charges at a bit line of a bottom array block. The switching device at a top array side is opened to drive a sense amplifier, and thus, the data read from the memory cell and retained at the bit line of the bottom array block is output to the outside. While the data is output in the above-described manner, a potential of the bit line of the top array block can be precharged to start a next read operation.

### CROSS-REFERENCE TO RELATED APPLICATION

This is a continuation of PCT International Application PCT/JP2008/003191 filed on Nov. 5, 2008, which claims priority to Japanese Patent Application No. 2008-117328 filed on Apr. 28, 2008. The disclosures of these applications including the specifications, the drawings, and the claims are hereby incorporated by reference in its entirety.

### BACKGROUND

The present disclosure relates to a nonvolatile semiconductor memory device such as an electrically erasable and programmable read-only memory (EEPROM), a flash memory, and the like, which is capable of retaining data even while power is not supplied thereto, and an electronic equipment using the semiconductor memory device.

Semiconductor memory devices including elements integrated on a semiconductor substrate for storing data are generally classified into two types: volatile memories capable of retaining data only while power is supplied thereto; and nonvolatile memories capable of retaining data even while power is not supplied thereto. Semiconductor memory devices of each of the two types are further classified by systems and uses. One of nonvolatile memories most widely used today is flash memories.

Flash memories are further classified into different types according to device configurations and array configurations thereof. Typical examples of flash memory types categorized according to device configurations are: the floating memory cell type; and the metal-nitride-oxide semiconductor (MNOS) memory cell type. In a flash memory of the floating memory cell type, each memory cell is configured so that a floating gate is formed on a channel of a metal-oxide semiconductor (MOS) transistor to be isolated by an oxide film or the like, and electrons are injected into or removed from the floating gate to change a threshold (hereinafter also referred to as Vt) of the memory cell, thereby storing data. On the other hand, in a flash memory of the MNOS memory cell type, each memory cell is configured so that an ONO film (i.e., a stacked film having a structure of a silicon oxide film/a silicon nitride film/a silicon oxide film) is formed on a channel of a MOS transistor, and electrons or holes are injected in traps in an ON film interface, thereby changing Vt. Since trapped electrical charges (electrons or holes) can hardly move, the electrical charges can locally stay on the channel. There is an MNOS memory configured, using this feature, so that a plurality of local charge portions are provided in a single memory cell to store information of a plurality of bits.

FIG. 15 is a cross-sectional view of a MNOS type memory cell. A local oxidation of silicon (LOCOS) 101 for device isolation, an ONO film 102, and a gate 103 are formed on a semiconductor substrate, and a diffusion layer 104 is formed under the LOCOS 101. The gate 103 is made of polysilicon, in general, and is used as a word line in a memory array. The diffusion layer 104 serves as a drain or a source of the memory cell, and is used as a buried bit line in the memory array. A region in which electrical charges are locally stored is denoted by 105.

FIG. 16 is a mnemonic symbol of the device of FIG. 15. In FIG. 16, a component corresponding to each component of FIG. 15 is denoted by the same reference character.

Typical examples of flash memory types categorized according to the array configurations are: the NAND type; and the NOR type. An NAND memory array is not suitable for high speed operation because a read current is small. However, a cell area in an NAND memory array is small, and is advantageous in increasing the memory capacity. Therefore, such NAND memory arrays have been mainly used for data storage. In contrast, a NOR memory array has a feature that it is suitable for high speed read operation. Taking advantage of this feature, NOR memory cell arrays have been mainly used as code storage memories for operating a processor.

As described above, using the features of the flash memories that data can be retained even after power is turned off and that increase in capacity is easy, applications of flash memories using many different methods have been expanded, and the production yield of such flash memories has been increased in various industrial fields.

However, there are also drawbacks of flash memories. For example, the data rewrite speed is low, the number of times for rewriting data is limited, and the like. To make up for such drawbacks, various approaches have been taken. As one of the approaches, there is a technique in which a flash memory is operated in combination with a buffer to temporarily store data. A volatile memory capable of operating at high speed is mainly used as the buffer, thereby compensating for low operation speed, a limited number of times for rewriting, and the like. Specifically, in the above-described NAND memory array configuration, the data read speed is also low in many cases, and therefore, this technique is very important. Examples where such drawbacks of flash memories are compensated for using a buffer will be specifically described hereinafter.

<Read Buffer>

A first example relates to a method in which read data is temporarily stored in a buffer to improve the data read speed. FIGS. 17-21 are diagrams illustrating a configuration according to the first example.

FIG. 17 is a block diagram of a known flash memory. The known flash memory includes an array block 1 of memory cells, a Y switch 2 (occasionally referred to as a “column decoder”), a sense amplifier (SA) 3, and a buffer 4. Note that an actual flash memory includes, in addition to the blocks shown in FIG. 17, various circuit blocks such as a row decoder, a power supply circuit, a control circuit, and the like, which are necessary for the operation of the flash memory. However, such circuit blocks do not relate to the present disclosure, and therefore, the description thereof is omitted. FIGS. 18-21 illustrate example internal configurations of the blocks shown in FIG. 17.

FIG. 18 illustrates an example internal configuration of the array block 1. In this example, a virtual ground array (VGA) which is comprised of MNOS memory cells and is configured to store information of a plurality of bits in a single memory cell is used. As shown in FIG. 18, a plurality of memory cells M01-M06, M11-M16 and M21-M26 are arranged in an array, and a gate of each of the memory cells is connected to one of word lines WL0, WL1 and WL2 each of which is connected to a common node in the lateral direction. For example, a control gate of each of the memory cells M01, M02, . . . and M06 is connected to the word line WL0. A source or a drain of each of the memory cells is connected to one of bit lines BL0-BL6 each of which is connected to a common node in the longitudinal direction. For example, a drain or a source of each of the memory cells M01, M11 and M21 is connected to one of the bit lines BL0 and BL1. In FIG. 18, only a part of the array is shown because of space limitations but, in general, more memory cells, bit lines and word lines are provided in the longitudinal and lateral directions in an actual array.

FIG. 19 illustrates an example internal configuration of the Y switch 2. In this example, an N-channel type MOS (NMOS) transistor is used as a switching device. As shown in FIG. 19, one of a drain and a source of each of NMOS transistors N0-N6 is connected to one of the bit lines BL0-BL6, and the other one of the drain and the source is connected to a data line DL connected to a common node. A gate of each of the NMOS transistors N0-N6 is connected to one of selection signals DS0-DS6 of the bit lines.

FIG. 20 illustrates an example internal configuration of the sense amplifier 3. In this example, a current mirror sense amplifier is used. In FIG. 20, P11 and P12 denote P-channel type MOS (PMOS) transistors, and N11, N12 and N13 denote NMOS transistors. When a sense amplifier enable signal SAE is activated, a potential of the data line DL and a potential of a reference REF are compared to each other and, based on a result of the comparison, a potential is output to a data line DB.

FIG. 21 illustrates an example internal configuration of the buffer 4. In this example, a latch circuit is used. In this latch circuit example, an output of an inverter INV2 is fed back to an input of an inverter INV1 to create a stable state, and data is stored. An NMOS transistor N21 is used as a switching device for connecting/disconnecting the data line DB to/from the input of the inverter INV1, and a state of the NMOS transistor N21 is controlled by a control signal CLK. Also, an NMOS transistor N22 is used as a switching device for connecting/disconnecting feedback of an output of the inverter INV2, and a state of the NMOS transistor N22 is controlled by a signal obtained by inverting the control signal CLK using an inverter INV3. Note that in general, an actual latch circuit includes, in addition to the circuits shown in FIG. 21, various circuits such as an interface for data passing and the like. However, the description of such circuits is omitted in FIG. 21.

Next, a general flow of the read operation will be described with reference to FIG. 17, and the function of the buffer 4 and advantages thereof will be described. First, in the array block 1, data stored in a memory cell is read in the form of a potential of one of the bit lines. The bit line from which the data has been read is connected to the sense amplifier 3. Then, the read potential and the potential of the reference REF are compared to each other to determine data, and a result of the determination is sent to the buffer 4, thereby latching (temporarily storing) the data. After the data is latched by the buffer 4, a next read operation is started in the array block 1, and at the same time, the data latched by the buffer 4 is output to the outside of the flash memory. That is, with the buffer 4 provided, simultaneous operations are allowed in the flash memory, thus realizing reduction in read time. In general, a time to perform the operation in the array block 1 is much longer than a time to output data from the buffer 4 to the outside of the buffer 4. Therefore, if the flash memory is configured to include multiple ones of the configuration of FIG. 17 so that read operations in multiple ones of the array block 1 are simultaneously performed and then data from multiple ones of the buffer 4 is sequentially output, the read time of the flash memory can be reduced. In an actual situation, it is relatively easy to increase the number of bits which are to be simultaneously read in the array block 1, and therefore, such a configuration is used in many cases.

Note that since those skilled in the art can easily think of the detail operation of each block, the description thereof will be omitted herein. In many cases, the above-described technique of improving the read speed using the buffer 4 is used not only for a nonvolatile memory but also for a volatile memory whose operation speed is intrinsically high to further increase the operation speed.

<Capacitance used for Data Read from Complementary Memory>

A second example relates to the read operation of a flash memory of the MNOS type in which a plurality of local charge portions are provided in a single memory cell and the local charge portions are caused to be in a complementary state, thereby storing data. FIG. 18 and FIGS. 22-26 are diagrams describing a configuration of the second example (see U.S. Pat. No. 7,333,368).

FIG. 22 is a block diagram of a known flash memory. The known flash memory includes an array block 1 of memory cells, a Y switch 5, a sense amplifier 6, and a buffer 7, and the array block 1 identified by the same reference character as that in FIG. 17 has the same internal configuration as that of the array block 1 of FIG. 17. Similarly to FIG. 17, an actual flash memory includes, in addition to the blocks shown in FIG. 22, various circuit blocks, but the description thereof is omitted.

FIGS. 23-25 illustrate example internal configurations of the blocks shown in FIG. 22. FIG. 23 illustrates an example internal configuration of the Y switch 5. Each of data lines DL0 and DL1 is connected to one of bit lines BL0-BL6 via one of switching devices S0 and S1, or is not connected to any bit line. As a specific method for realizing the switching devices S01 and S1, as shown in FIG. 19, a circuit comprised of an MOS transistor can be used. FIG. 24 illustrates an example internal configuration of the sense amplifier 6. In this case, a dynamic sense amplifier is used. In FIG. 24, P11, P12 and P13 denote PMOS transistors, and N11, N12 and N13 denote NMOS transistors. When sense amplifier enable signals SAE and/SAE are activated, potentials of the data lines DL0 and DL1 are compared to each other, and a difference between the potentials is amplified. FIG. 25 illustrates an example internal configuration of the buffer 7. In this case, capacitors C0 and C1 in which one of electrodes is connected to the ground are used.

FIG. 26 is a diagram illustrating particular ones of the components shown in FIG. 18 and FIGS. 23-25 which are necessary for describing this example. In this example, a method in which two local charge portions are provided in a single memory cell and are caused to be in a complementary state to store data is used. Specifically, electrons are injected into a local charge portion of a memory cell M01 located at the left hand side of FIG. 26 to cause Vt to be high, and electrons are removed from a local charge portion of the memory cell M01 located at the right hand side of FIG. 26 to cause Vt to be low. This state is defined as data 0. An opposite state to the above-described state for the local charge portions, i.e., a state where Vt is low at the left hand side and is high at the right hand side is defined as data 1. As described above, data is stored using complementary two different states, so that the reliability of the flash memory can be improved.

Next, the data read operation in a complementary memory will be described with reference to FIG. 26, and the function of the buffer 7 and advantages thereof will be described. In a data storing method of this example, two local charge portions are provided in a single memory cell, and thus, a read method used in a complementary memory in which a complementary state is created between different memory cells cannot be used. That is, to determine data, two local charge portions in a complementary state have to be read, but data read from the two local charge portions cannot be simultaneously performed since the two local charge portions are provided in a single memory cell. Thus, the buffer 7 for temporarily retaining a result of data read from one of the local charge portions is necessary, and the capacitors C0 and C1 are used as the buffer 7.

As steps for reading data using the capacitors C0 and C1, first, with a switching device S1 in a close state, a state of the local charge portion of the memory cell M01 at the right hand side is read to the bit line BL1, and the read data is transferred to the capacitor C1 in the form of potential. After transferring, the switching device S1 is opened, and a switching device S0 is closed. Next, a state of the local charge portion of the memory cell M01 at the left hand side is read to the bit line BL0, and the read data is transferred to the capacitor C0 in the form of potential. After transferring, the switching device S0 is opened, and the sense amplifier 6 is enabled to amplify a difference between potentials stored in the capacitors C0 and C1, thereby determining data.

As described above, by using the buffer 7 comprised of the capacitors C0 and C1, data can be read from a complementary memory cell in which a complementary state is created in a single memory cell.

<Write Buffer>

A third example relates to a method in which write data is temporarily stored in a buffer to improve the write speed. FIG. 18, FIG. 19 and FIGS. 27-29 are diagrams describing a configuration of the third example.

FIG. 27 is a block diagram illustrating a known flash memory. The known flash memory includes an array block 1 of memory cells, a Y switch 2, a driver 8, and a buffer 9, and the array block 1 and the Y switch 2 identified by the same reference characters as those in FIG. 17 have the same internal configurations as those of the array block 1 and the Y switch 2 of FIG. 17. Similarly to FIG. 17, an actual flash memory includes, in addition to the blocks shown in FIG. 27, various circuit blocks, but the description thereof is omitted.

FIGS. 28 and 29 illustrate example internal configurations of the blocks shown in FIG. 27. FIG. 28 illustrates an example internal configuration of the driver 8. In this example, inverters INV1 and INV2 are provided to form a two-stage configuration. FIG. 29 illustrates an example internal configuration of the buffer 9. In this example, a latch circuit that is the same as the latch circuit of the first example shown in FIG. 21 is arranged so that locations of an input and an output thereof are reversed.

Next, a general flow of the write operation will be described with reference to FIG. 27, and the function of the buffer and advantages thereof will be described. First, data DI input from the outside of the flash memory is latched by the buffer 9. The driver 8 receives an output from the buffer 9, and enables a bit line connected by the Y switch 2 to perform a write operation. In this case, input of write data from the outside of the flash memory does not have to be continuously performed, thus improving the usability. Also, when the number of the latch circuits serving as the buffer 9 is increased to increase an amount of data temporarily stored, data continuously written therein is analyzed and a write algorithm is adjusted, thereby reducing a write time.

<RAM>

A fourth example relates to a method for building a computer system using a flash memory. FIG. 30 is a diagram describing a configuration of the fourth example.

FIG. 30 is a configuration diagram of a known computer system. The computer system includes a processor 10, a flash memory 11, and a static random access memory (SRAM) 12. The processor 10, the flash memory 11 and the SRAM 12 are connected together via an address bus 13 and a data bus 14. Note that an actual computer system includes, in addition to the components shown in FIG. 30, various components such as a peripheral, an I/O port for performing communication with the peripheral, a control bus for performing control, and the like, which are necessary for the system. However, such components do not relate to the present disclosure, and therefore, the description thereof is omitted.

Next, a flow of processing in the computer system will be described with reference to FIG. 30, and the function of the SRAM 12 used as a buffer and advantages thereof will be described. A method for performing processing in the computer system and necessary data are stored in a flash memory 11 which is a read-only memory (ROM), and the processor 10 reads the method and data from the flash memory 11 to execute processing. In the process of processing, values obtained during calculation, parameters used for controlling the processing, and the like have to be temporarily stored. If such values and parameters can be temporarily stored using the flash memory 11, the SRAM 12 of FIG. 30 is not necessary, and thus, a computer system can be comprised of only the processor 10 and the flash memory 11. However, write and read of such temporarily stored data have to be performed frequently and at high speed, but the rewrite speed of the flash memory 11 is several orders of magnitude lower than required speed and the number of times for rewriting data in the flash memory 11 is limited. Accordingly, the flash memory 11 cannot temporarily store the values and parameters. Therefore, a nonvolatile memory which can rewrite data at high speed and on which data can be rewritten unlimited number of times has to be additionally provided, and thus, the SRAM 12 is used to temporarily store data, thereby achieving the computer system.

As described above, if a nonvolatile memory is used in combination with a volatile memory capable of high speed operation, the usability of the nonvolatile memory is improved. Meanwhile, to overcome the above-described drawbacks of flash memories and replace flash memories, new nonvolatile memories such as a ferroelectric memory (FeRAM), a phase change memory (PRAM), a magnetic memory (MRAM), a resistive memory (ReRAM) an the like have been proposed, developed and commercialized. However, such replacement has not yet realized in the major field of application (market) of flash memories. It is likely that the capacity of a flash memory will be increased more and more and the cost for producing a flash memory will be reduced more and more. In this regard, it is not easy to develop a new nonvolatile memory that is as good as that of such a flash memory. Therefore, techniques for complementing the above-described drawbacks of flash memories will be as important as the present.

### SUMMARY

In each of the above-described examples, to improve the usability of a flash memory, a circuit such as a buffer which is capable of temporarily storing data is necessary, and thus, the chip area of a flash memory and the number of components of a system are increased. Furthermore, to obtain a greater advantage of such a buffer, the capacity or the number of the buffer has to be increased. Therefore, there is a dilemma in which, as the usability is improved, the chip area and the number of components (prices) are increased, and thus increasing costs.

It is an object of the present disclosure to prevent increase in chip area caused by realizing a buffer function in a nonvolatile memory as typified by a flash memory and the like, or to prevent increase in the number of components (prices) of a system using a nonvolatile memory. Thus, a dilemma of advantages of a buffer and increase in cost is resolved.

To achieve the above-described object, a semiconductor memory device according to the present disclosure is configured so that, using a bit line capacitance of a flash memory, data is temporarily stored at operation (data rewrite/read) speed equal to that of a dynamic random access memory (DRAM).

By using a technique according to the present disclosure, a buffer function can be realized while increase in area is hardly caused, and the usability of a nonvolatile memory as typified by a flash memory can be improved. There might be cases where an area is slightly increased to realize the function, but an additional area is not increased in proportion to the capacity of the buffer at least. An excellent advantage can be exhibited especially when a buffer has a large capacity.

Thus, a nonvolatile memory with good usability is implemented at low cost, so that the performance of an electronic equipment using the nonvolatile memory can be improved, and better quality products can be offered to the society.

### BRIEF DESCRIPTION OF THE DRAWINGS

FIG. 1 is a block diagram of a flash memory according to a first embodiment.

FIG. 2 is a detailed diagram of the flash memory of the first embodiment.

FIG. 3 is an operation timing chart according to the first embodiment.

FIG. 4 is a block diagram illustrating a variation of the flash memory of the first embodiment.

FIG. 5 is a block diagram of a flash memory according to second and third embodiments.

FIG. 7 is an operation timing chart according to the third embodiment.

FIG. 8 is a block diagram of a flash memory according to a fourth embodiment.

FIG. 9 is a circuit diagram of a memory cell array block according to the fourth embodiment.

FIG. 10 is a detailed diagram of the flash memory of the fourth embodiment.

FIG. 11 is a block diagram of a flash memory according to fifth and seventh embodiments.

FIG. 12 is a configuration diagram of a computer system according to a sixth embodiment.

FIG. 13 is a configuration diagram of a computer system according to an eighth embodiment.

FIG. 14 is a block diagram of a flash memory according to the eighth embodiment.

FIG. 15 is a cross-sectional view illustrating a configuration of a known memory cell device.

FIG. 16 is a conceptual diagram illustrating a mnemonic symbol of the known memory device.

FIG. 17 is a block diagram of a flash memory according to a first known example.

FIG. 18 is a circuit diagram of a memory cell array block according to the first known example.

FIG. 19 is a circuit diagram of a Y switch according to the first known example and a third known example.

FIG. 20 is a circuit diagram of a sense amplifier according to the first known example.

FIG. 21 is a circuit diagram of a buffer according to the first known example.

FIG. 22 is a block diagram of a flash memory according to a second known example.

FIG. 23 is a circuit diagram of a Y switch according to the second known example.

FIG. 24 is a circuit diagram of a sense amplifier according to the second known example.

FIG. 25 is a circuit diagram of a buffer according to the second known example.

FIG. 26 is a detailed diagram of the flash memory of the second known example.

FIG. 27 is a block diagram of a flash memory according to a third known example.

FIG. 28 is a circuit diagram of a driver according to the third known example.

FIG. 29 is a circuit diagram of a buffer according to the third known example.

FIG. 30 is a configuration diagram of a computer system according to a fourth known example.

### DETAILED DESCRIPTION

### First Embodiment

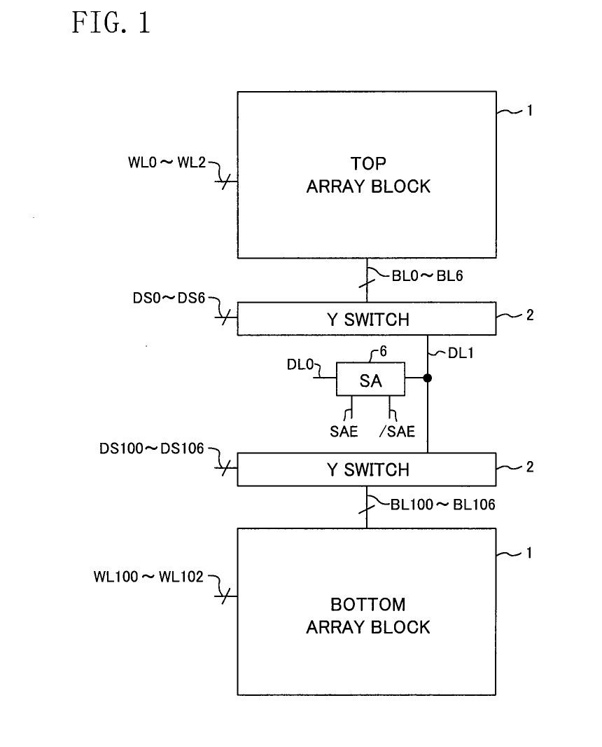

A first embodiment provides a solution to problems of the method in which read data is temporarily stored in a buffer to improve the read speed, which has been described in the first example in the BACKGROUND section. FIGS. 1-4 are diagrams describing this embodiment.

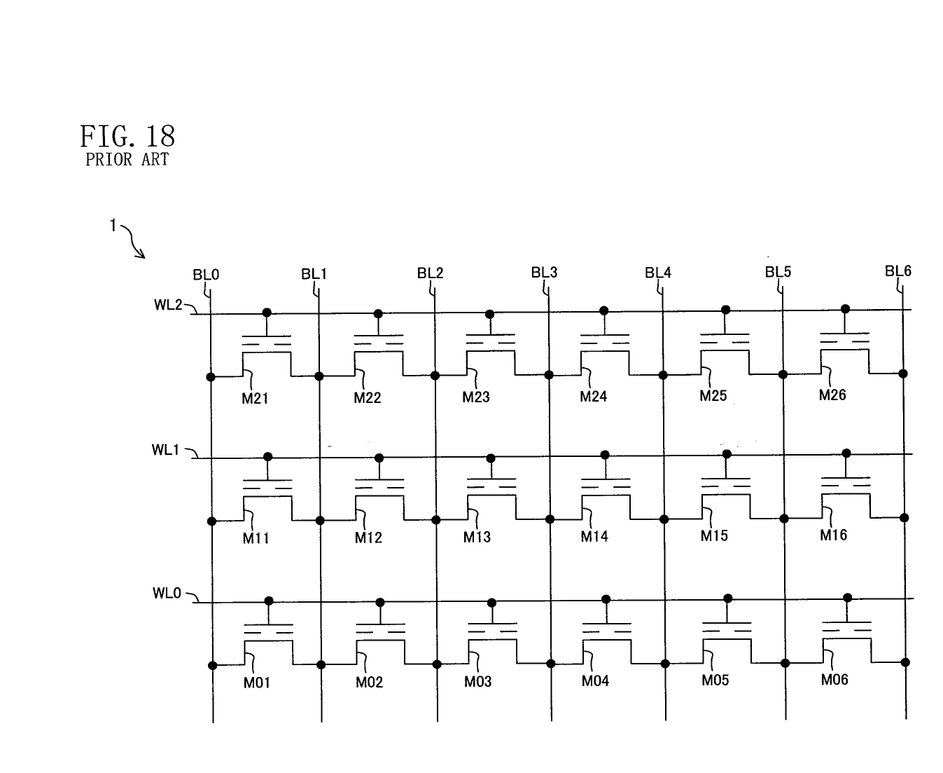

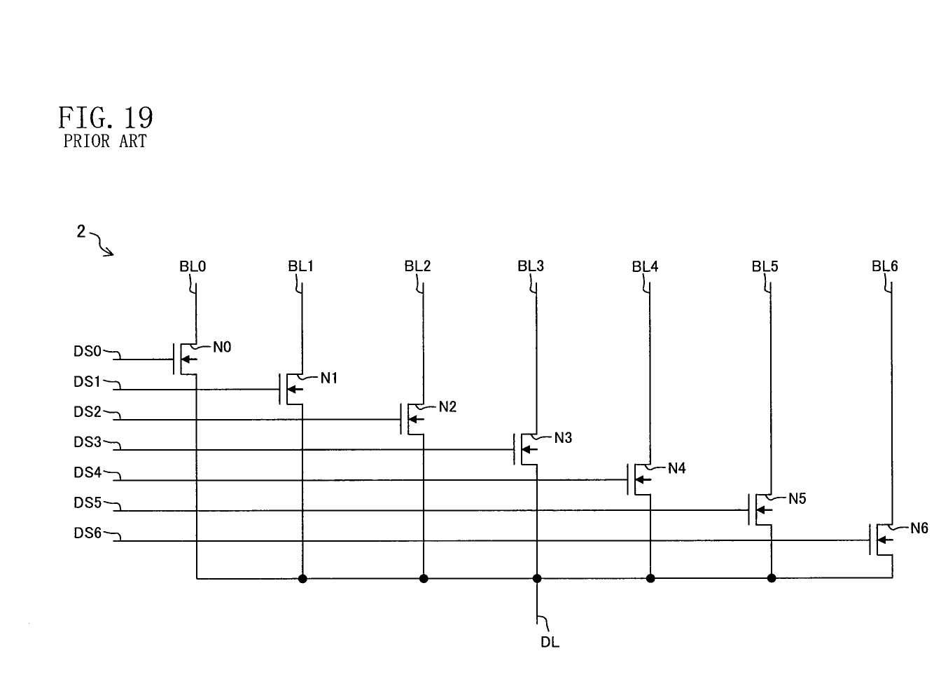

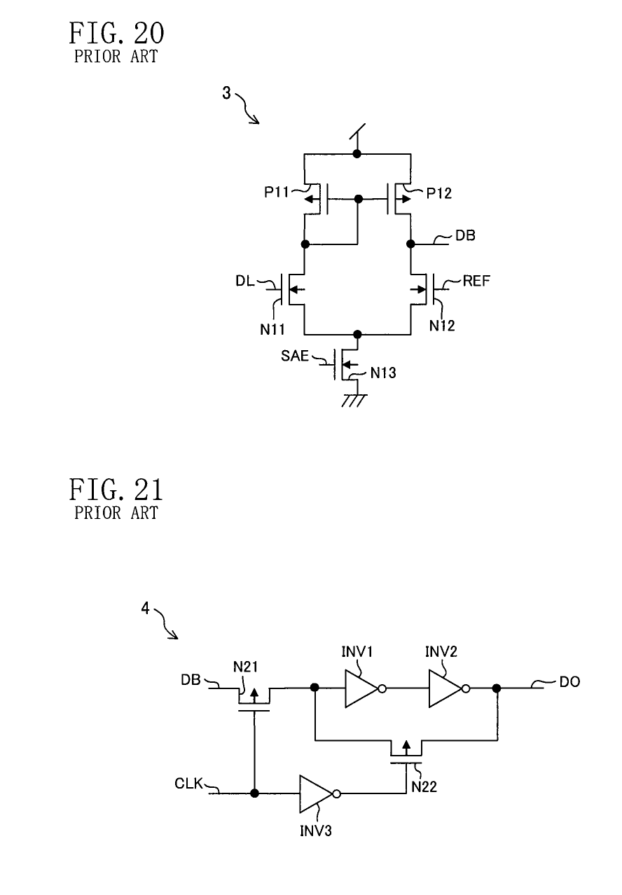

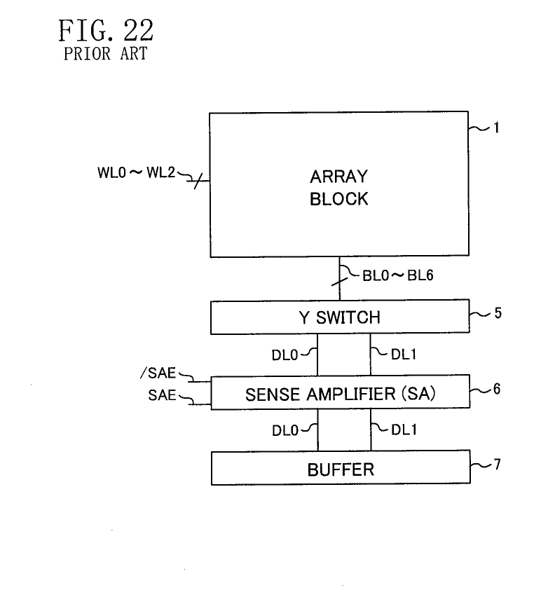

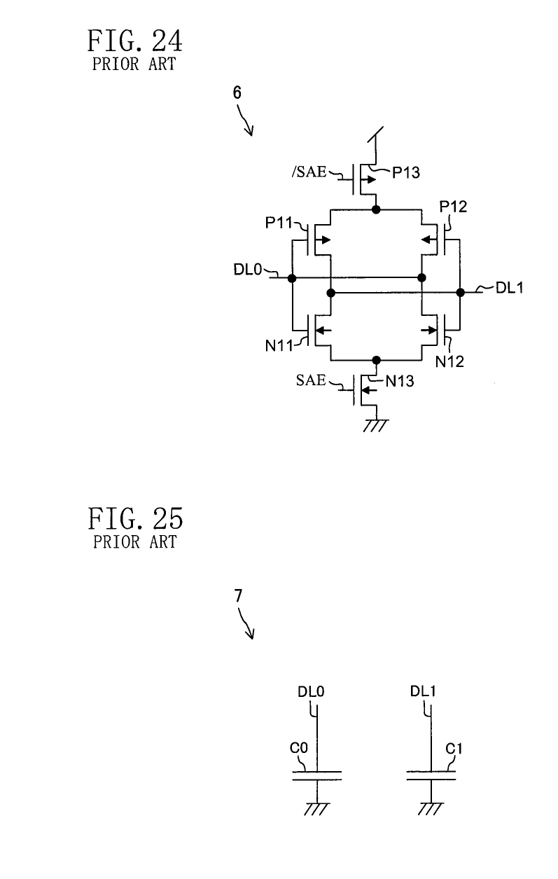

FIG. 1 is a block diagram of a flash memory according to the present disclosure. The flash memory of FIG. 1 has an open array architecture in which an array block 1 of memory cells and a Y switch 2 are provided both above and under (on the top and bottom of) a sense amplifier 6 as viewed in FIG. 1, and each block identified by the same reference character as that in FIGS. 17 and 22 has the same internal configuration as that of FIGS. 17 and 22. Note that an actual flash memory includes, in addition to the blocks shown in FIG. 1, various circuit blocks such as a row decoder, a power supply circuit, a control circuit and the like, which are necessary for the operation of the flash memory. However, such circuit blocks do not relate to the present disclosure, and therefore, the description thereof is omitted. The block configuration of FIG. 1 is merely an example, and the present disclosure is not limited to the configuration. Similarly, the example internal configurations of the blocks shown in FIG. 18, FIG. 19 and FIG. 24 are merely illustrative examples, and the present disclosure is not limited to the configurations. For example, in the internal configuration of the array block 1 of FIG. 18, NMOS memory cells are used. However, the present disclosure can be implemented also by using various types of cells and arrays described in the BACKGROUND section. Also, the internal configuration of the sense amplifier 6 of FIG. 24 is an internal configuration of a dynamic sense amplifier. However, no problem is caused in implementing the present disclosure by using the current mirror sense amplifier of FIG. 20 or other methods. Other types of switches can be used, instead of the Y switch 2 of FIG. 19, without causing any problem.

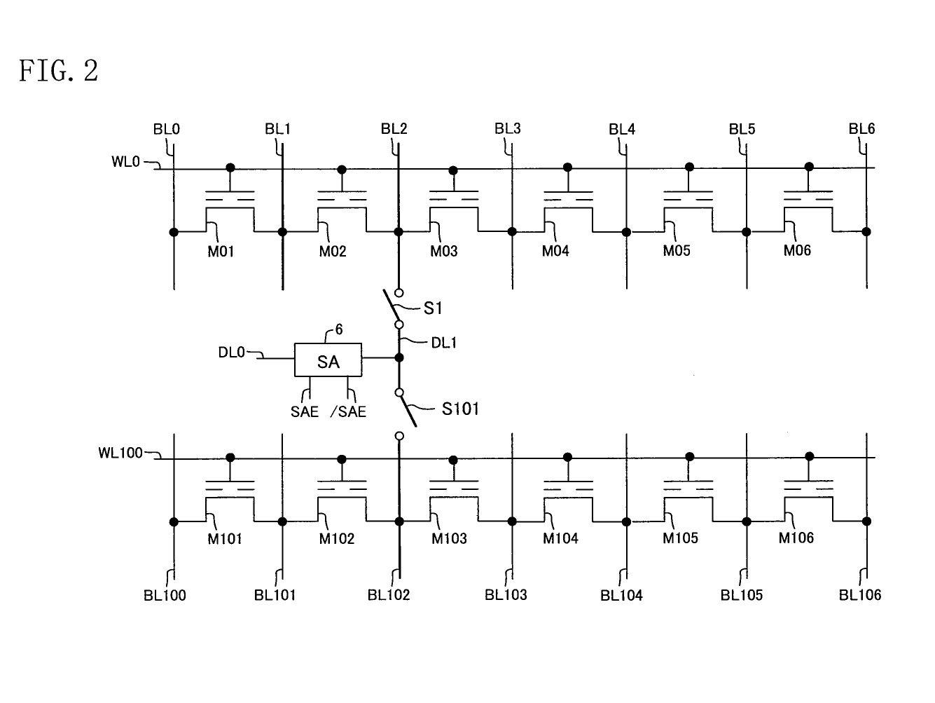

FIG. 2 is a diagram illustrating particular ones of the components shown in FIG. 18 and FIG. 19 which are necessary for describing the first embodiment. Note that memory cells M101-M106, bit lines BL100-BL106, and a word line WL100 are equivalent to the memory cells M01-M06, the bit lines BL0-BL06, and the word line WL0 shown in FIG. 18, respectively, although being identified by different reference characters. A memory cell M02 is a target cell from which data is to be read, and data stored in the memory cell M02 is read to a bit line BL2 in the form of potential. Also, the bit line BL2 is connected to a data line DL1 via a switching device S1, and the data line DL1 is connected to the sense amplifier 6. The switching device S1 is an NMOS transistor N2 controlled by a selection signal DS2 in FIG. 19. However, for simplicity of the description herein, the switching device S1 is shown as a switching device describing the function of the NMOS transistor N2, and a switching device S101 configured to connect the data line DL1 to a bit line BL102 has the same function. Also, another data line DL0 is connected to the sense amplifier 6, and a reference potential for determining data is applied thereto.

A read operation according to the present disclosure will be described hereinafter with reference to FIG. 2, and advantages thereof will be clearly shown. In an initial state, the word lines WL0 and WL100 are at the Low level and in a close state, and the bit lines BL0-BL6 and the bit lines BL100-BL106 are in a Hi-z (high impedance) state after having been precharged to the Low level. The switching devices S1 and S101 are all in an open state. Next, the switching devices S1 and S101 are closed, so that the bit line BL2 connected to a source of the memory cell M02 which is a target cell from which data is to be read is connected to the bit line BL102, and the bit line BL1 connected to a drain of the memory cell M02 is driven to the High level. Thereafter, the word line WL0 is caused to be at the High level to read data stored in a local charge portion of the memory cell M02 at the right hand side in FIG. 2. For example, when the local charge portion is in an erased state, a current flows in the memory cell M02, and thus, the potentials of the bit lines BL2 and BL102 increase. On the other hand, when the local charge portion is in a written state, a current does not flow in the memory cell M02, and thus, the potentials of the bit lines BL2 and BL102 do not change and are maintained substantially at the Low level. After a lapse of a certain time, the word line WL0 is caused to be at the Low level, the switch S1 is opened, and the sense amplifier 6 is enabled. In this case, the data lines DL0 and DL1 are connected to inputs of the sense amplifier 6, a reference cell potential is retained at the data line DL0, and a potential when data stored in the local charge portion of the memory cell M02 at the right hand side is read is retained at the data line DL1. A difference between the potentials is amplified to determine data. While the determined data is retained at the bit line BL102, the potential of the bit line BL2 can be changed without affecting the determined data since the switching device S1 is in an open state. Thus, while the data retained at the bit line BL102 is output to the outside of the flash memory, the potential of the bit line BL2 can be precharged to start a next read operation.

This means that the same advantages as those of the read buffer described in the first example in the BACKGROUND section are achieved. However, the buffer 4 of FIG. 17 is not provided as a component of the present disclosure, and thus, increase in a chip area due to the buffer 4 is not caused. Although it might seem that the array block 1 at the bottom side corresponds to the buffer 4, nonvolatile data can be stored in the array block 1 at the bottom side, and the array block 1 at the bottom side is not added as a buffer for temporarily storing read data. That is, the bit lines at the bottom side are components which exist even when a buffer is not used. Note that when nonvolatile data is read from a memory cell provided in the array block 1 at the bottom side, the data is retained using a bit line provided in the array block 1 at the top side.

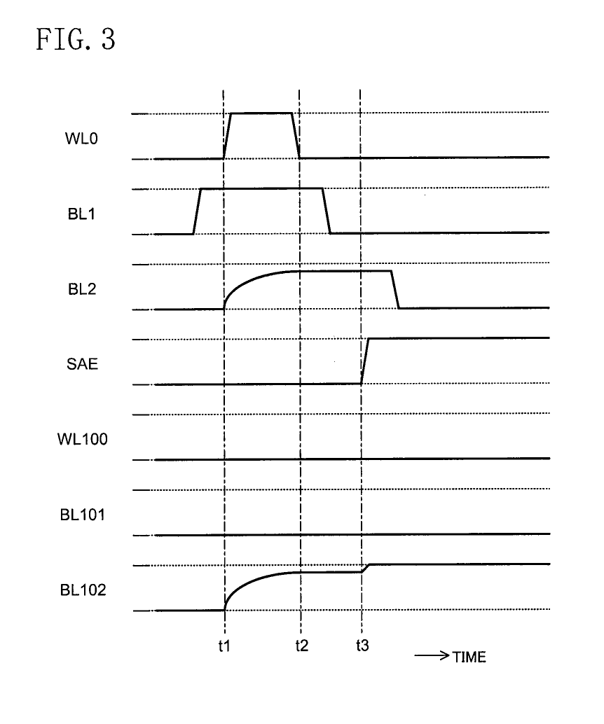

FIG. 3 complements the description of the read operation according to the present disclosure which has been made with reference to FIG. 2, and shows that the bit line BL2 is precharged to the Low level again to prepare a next read while the sense amplifier 6 is enabled to retain data at the bit line BL102. In FIG. 3, t1 represents a timing of start of driving the word line WL0, t2 represents a timing of end of driving the word line WL0, and t3 represents a timing of enabling the sense amplifier 6.

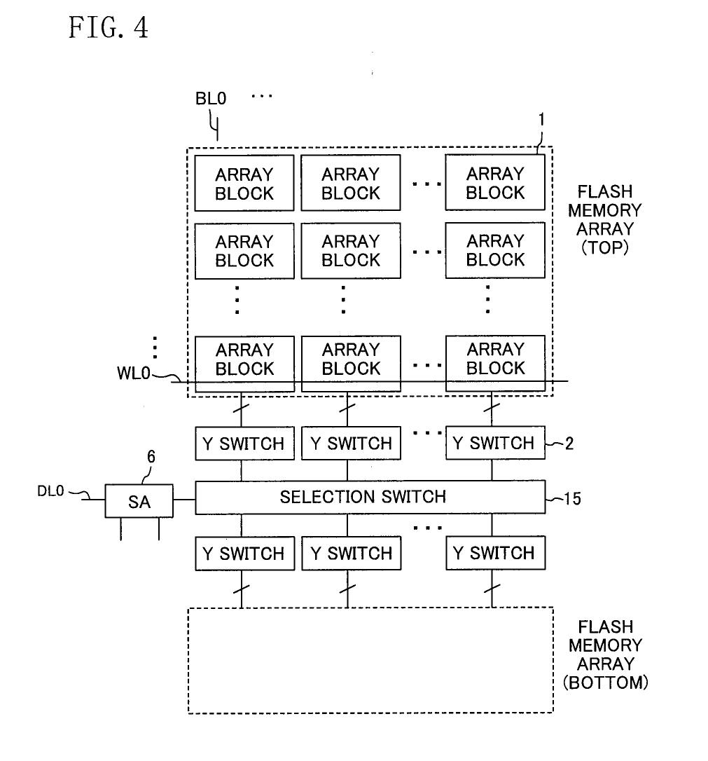

FIG. 4 is a block diagram illustrating the case where a single sense amplifier 6 is shared by a plurality of array blocks 1 and a plurality of Y switches 2. In a VGA used in this embodiment, when a word line is opened at the time of read, bit lines are connected to one another via memory cells, and thus, simultaneous read is performed to one memory cell of each of the array blocks. However, in a typical VGA type flash memory, as shown in FIG. 4, it is normal that multiple ones of array blocks 1 are provided, and in this case, data can be read simultaneously from a plurality of memory cells to bit lines. As described above, potentials read to a plurality of bit lines in the array blocks at the top side are transferred to bit lines of the array blocks at the bottom side. Thereafter, data is determined while a bit line which is to be connected to the sense amplifier 6 is switched by a selection switch 15, so that data can be continuously output to the outside of the flash memory at high speed and, at the same time, a next read operation can be started in the array blocks at the top side. As described above, the read time can be further reduced by simultaneously reading data from a plurality of memory cells, but increase in area is not caused because existing bit lines are used.

Note that when the array block 1 is not VGA, data can be simultaneously read from a plurality of memory cells in the same array block. In such a case, if the Y switch 2 has the function of simultaneously connecting a plurality of bit lines in array blocks at the top and bottom sides together and the function of selecting the plurality of bit lines to connect them to the sense amplifier 6, the above-described continuous read can be performed in memory cells in the same array block. Note that those skilled in the art probably can easily design a configuration of the Y switch to realize the above-described functions, and therefore, the description thereof will be omitted.

### Second Embodiment

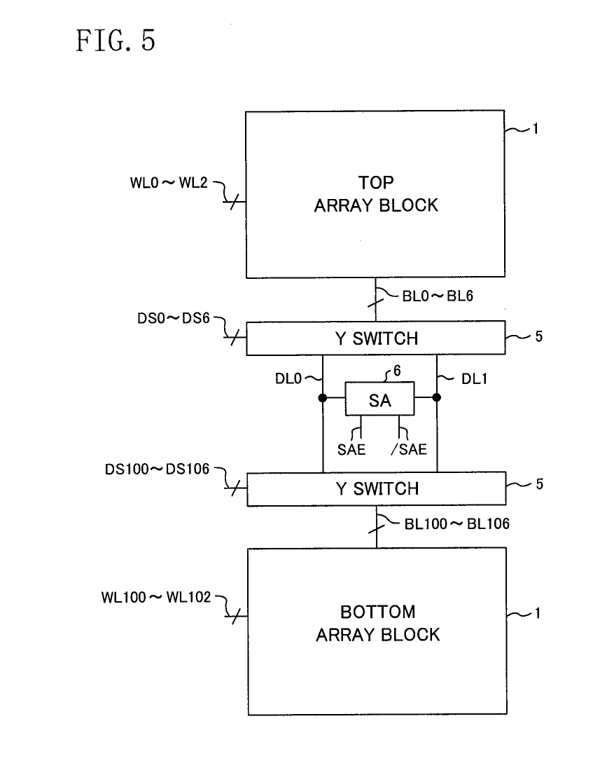

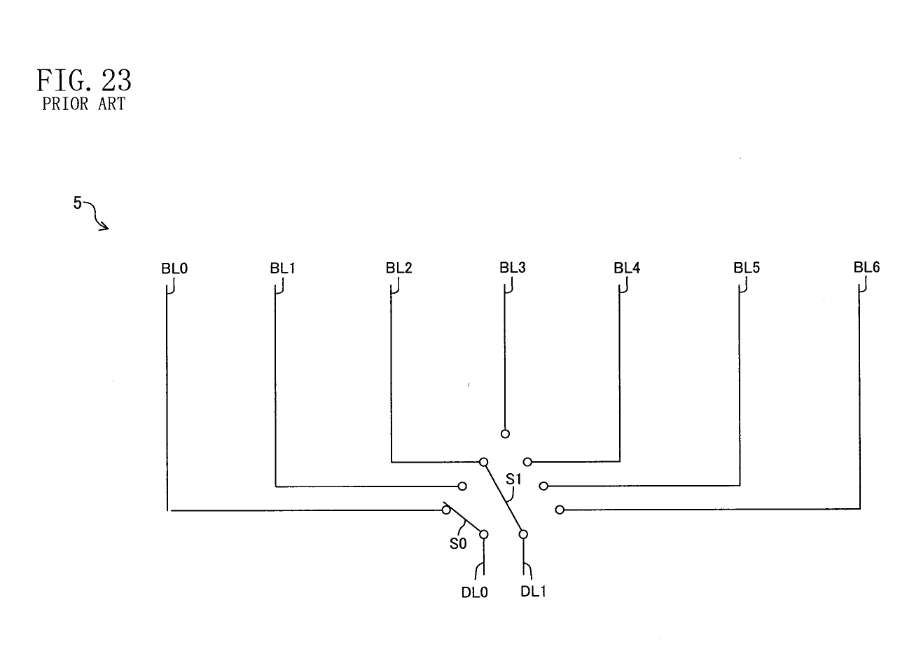

FIG. 5 is a block diagram of a flash memory according to a second embodiment. The flash memory of FIG. 5 has an open array architecture in which an array block 1 of memory cells and a Y switch 5 are provided both above and under (on the top and bottom of) a sense amplifier 6 as viewed in FIG. 5, and each block identified by the same reference character as that in FIGS. 17 and 22 has the same internal configuration as that of FIGS. 17 and 22. Note that an actual flash memory includes, in addition to the blocks shown in FIG. 5, various circuit blocks, but the description thereof is omitted. The block configuration of FIG. 5 and the example internal configurations of the blocks shown in FIG. 18, FIG. 23 and FIG. 24 are merely illustrative examples, and the present disclosure is not limited to the configurations.

FIG. 6 is a diagram illustrating particular ones of the components shown in FIG. 18 and FIG. 23 which are necessary for describing the second embodiment. The flash memory of the second embodiment is different from the flash memory of the first embodiment in that the data line DL0 to which the reference potential is applied can be connected to bit lines in array blocks at the top and bottom sides via the switching device S0 or S100.

In contrast to the first embodiment, since the flash memory of this embodiment has the configuration of FIG. 6, the reference potential can be generated at a bit line in an array block at the bottom side. In the dynamic sense amplifier 6 used in the description, an input signal is driven, and thus, the reference potential is changed at the time of determining data. Therefore, the reference cell potential has to be reset for next read. In the continuous read described in the first embodiment, a time to recover the reference potential is a problem. However, if the reference cell potential is generated at a plurality of bit lines in advance, even a dynamic sense amplifier such as the sense amplifier 6 can perform continuous read at high speed.

### Third Embodiment

A third embodiment provides a solution to problems of the method, described in the second example in the BACKGROUND section, for performing a read operation in a flash memory of the MNOS type in which a plurality of local charge portions are provided in a single memory cell and the plurality of local charge portions are caused to be in a complementary state to store data. FIGS. 5-7 are diagrams describing this embodiment. FIGS. 5 and 6 are also used to describe the second embodiment, and a configuration according to the third embodiment is not different from that of the second embodiment. However, nonvolatile data is stored in a memory cell using a different method, and therefore, a different method for performing a read operation is used.

A read operation according to the present disclosure will be described hereinafter with reference to FIG. 6, and advantages thereof will be clearly shown. In an initial state, the word lines WL0 and WL100 are at the Low level and in a close state, and the bit lines BL0-BL6 and the bit lines BL100-BL106 are in a Hi-z state after having been precharged to the Low level. The switching devices S0, S1, S100 and S101 are all in an open state. Next, the switching devices S1 and S101 are closed, so that the bit line BL2 connected to a source of the memory cell M02 which is a target cell from which data is to be read is connected to the bit line BL102, and the bit line BL1 connected to a drain of the memory cell M02 is driven to the High level. Thereafter, the word line WL0 is caused to be at the High level to read data stored in the local charge portion of the memory cell M02 at the right hand side in FIG. 6. For example, when the local charge portion is in an erased state, a current flows in the memory cell M02, and thus, the potentials of the bit lines BL2 and BL102 increase. On the other hand, when the local charge portion is in a written state, a current does not flow in the memory cell M02, and thus, the potentials of the bit lines BL2 and BL102 do not change and are maintained substantially at the Low level. After a lapse of a certain time, the word line WL0 is caused to be at the Low level, and the bit line BL1 and the bit line BL0 which has been changed from the Low level due to the neighbor effect are returned to the Low level to be in the Hi-z state. After the switching device S1 is opened, the switching devices S0 and S100 are closed, so that the bit line BL1 connected to the source of the memory cell M02 which is a target cell from which data is to be read is connected to the bit line BL101, and the bit line BL2 and the word line WL0 are caused to be at the High level, thereby reading data stored in the local charge portion of the memory cell M02 at the left hand side in FIG. 6. When the local charge portion of the memory cell M02 at the right hand side is in an erased state, the local charge portion thereof at the left hand side is in a written state, and thus, a current does not flow in the memory cell M02, so that the potentials of the bit lines BL1 and BL101 are maintained substantially at the Low level. On the other hand, when the local charge portion of the memory cell M02 at the right hand side is in a written state, the local charge portion thereof at the left hand side is in an erased state, and thus, a current flows in the memory cell M02, so that the potentials of the bit lines BL1 and the BL101 increase. After a lapse of a certain time, the word line WL0 is caused to be at the Low level, the switching device S0 is opened, and the sense amplifier 6 is enabled. In this case, the data lines DL0 and DL1 are connected to inputs of the sense amplifier 6, the potential at the time when data stored in the local charge portion of the memory cell M02 at the left hand side is read is retained at the data line DL0 using the capacitance of the bit line BL101, and the potential when data stored in the local charge portion of the memory cell M02 at the right hand side is read is retained at the data line DL1 using the capacitance of the bit line BL102. A difference between the potentials is amplified to determine data.

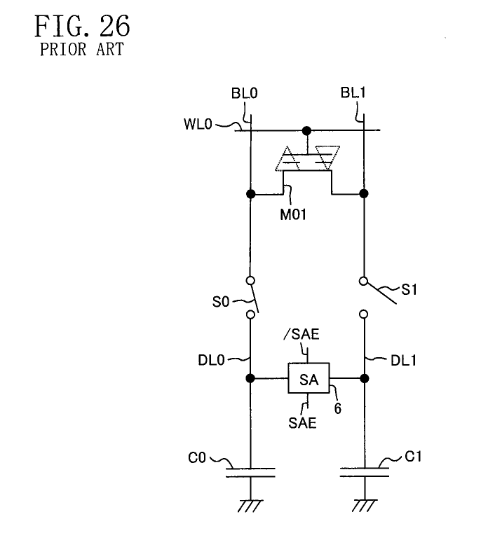

By performing the above-described operation, data in a complementally memory cell which could not be read at a time according to a known method can be read. This means that the same advantages as those described in the second example in the BACKGROUND section, in which capacitors are used, are achieved. However, the capacitors C0 and C1 of FIG. 26 are not provided as components of the present disclosure, and thus, increase in a chip area due to capacitors is not caused. Although it might seem that bit lines at the bottom side corresponds to the capacitors, nonvolatile data can be stored in the array block 1 at the bottom side, and the array block 1 at the bottom side is not added as a buffer for temporarily storing read data. That is, the bit lines at the bottom side are components which exist even when a buffer is not used. Note that when nonvolatile data is read from a complementary memory cell provided in the array block 1 at the bottom side, the data is retained using a bit line provided in the array block 1 at the top side.

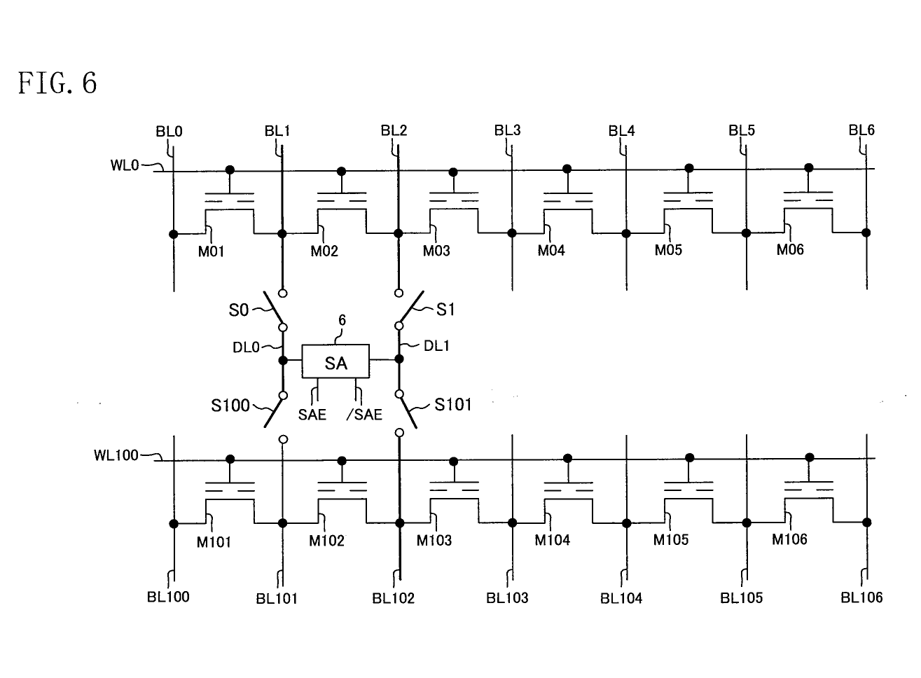

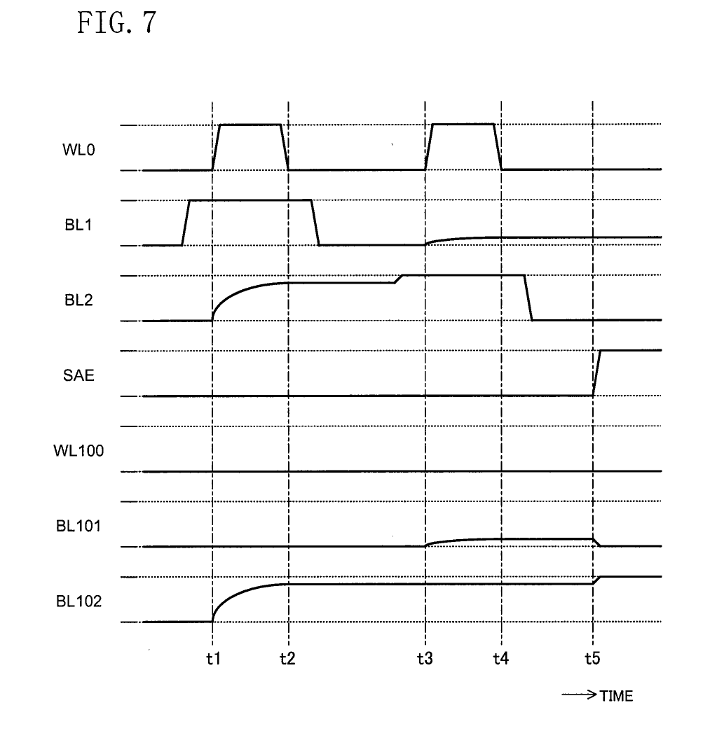

FIG. 7 complements the description of the read operation according to the present disclosure which has been made with reference to FIG. 6, and shows that data read from a memory cell is temporarily retained using the capacitances of the bit lines BL101 and the BL102. In FIG. 7, t1 represents a timing of start of driving the word line WL0 for reading data stored in the local charge portion at the right hand side, t2 represents a timing of end of driving the word line WL0, t3 represents a timing of start of driving the word line WL0 for reading data stored in the local charge portion at the left hand side, t4 represents a timing of end of driving the word line WL0, and t5 represents a timing of enabling the sense amplifier 6.

Also, in this embodiment, as in the first embodiment, data is simultaneously read from a plurality of memory cells to bit lines, and data is determined while a bit line which is to be connected to the sense amplifier 6 is switched by a selection switch. Thus, data can be continuously output at high speed, and the read time can be reduced.

### Fourth Embodiment

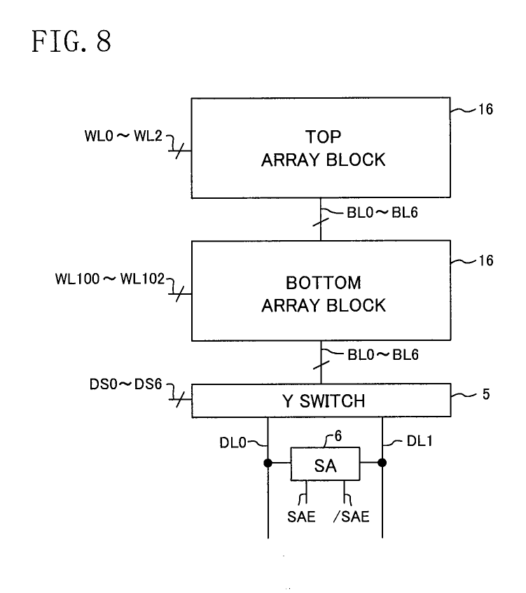

A fourth embodiment provides a solution to problems of the method, described in the second example in the BACKGROUND section, for performing a read operation in a flash memory of the MNOS type in which a plurality of local charge portions are provided in a single memory cell and the plurality of local charge portions are caused to be in a complementary state, thereby storing data. The solution is used when the flash memory has a hierarchical bit line structure. FIGS. 8-10 are diagrams describing this embodiment. Note that the present disclosure is not limited to a solution method used when a flash memory has a hierarchical bit line structure, but various solution methods including the method described in the third embodiment can be implemented.

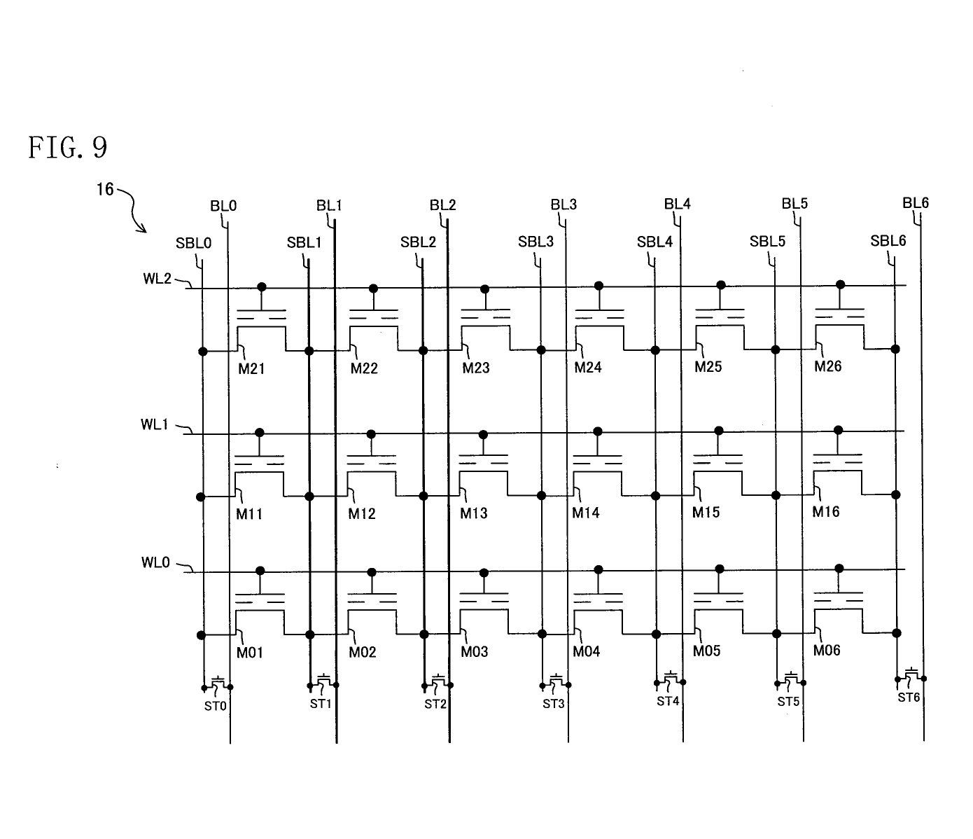

FIG. 8 is a block diagram of a flash memory according to the fourth embodiment. The flash memory of FIG. 8 has a folded array architecture in which two memory array blocks 16, i.e., top and bottom side memory array blocks and a Y switch 5 are arranged above a sense amplifier 6 as viewed in FIG. 8. Each block identified by the same reference character as that in FIG. 22 has the same internal configuration as that of FIG. 22. Note that an actual flash memory includes, in addition to the blocks shown in FIG. 8, various circuit blocks, but the description thereof is omitted. The block configuration of FIG. 8, the internal configuration of the memory array blocks 16 of FIG. 9, and the example internal configurations of the blocks shown in FIGS. 23 and 24 are merely illustrative examples, and the present disclosure is not limited to the configurations. For example, in FIG. 8, only two array blocks 16 are shown, but even if three or more array blocks are provided, there is no problem.

FIG. 9 illustrates an example internal configuration of the array block 16. FIG. 9 shows an example where in the VGA in the BACKGROUND section, which is comprised of MNOS memory cells and is configured to store information of a plurality of bits in a single memory cell, bit lines are in a hierarchical structure. As shown in FIG. 9, a plurality of memory cells M01-M06, M11-M16 and M21-M26 are arranged in an array, and a gate of each of the memory cells is connected to one of word lines WL0, WL1 and WL2 each of which is connected to a common node in the lateral direction. For example, a control gate of each of the memory cells M01, M02, . . . and M06 is connected to the word line WL0. A source or a drain of each of the memory cells is connected to one of sub-bit lines SBL0-SBL6 each of which is connected to a common node in the longitudinal direction. For example, the drain or the source of each of the memory cells M01, M11 and M21 is connected to one of the sub-bit lines SBL0 and SBL1. The sub-bit lines SBL0-SBL6 are respectively connected to the bit lines (occasionally referred to as “main bit lines” to distinguish the bit lines from the sub-bit lines) BL0-BL6 via selection transistors ST0-ST6. In the example of FIG. 9, NMOS transistors are used as the selection transistors ST0-ST6, and connection/disconnection of the sub-bit lines SBL0-SBL6 to/from the bit lines BL0-BL6 is controlled by application of a voltage to the gates of the selection transistors ST0-ST6. In FIG. 9, only a part of the array is shown because of space limitations but, in general, more memory cells, sub-bit lines, bit lines and word lines are provided in the longitudinal and lateral directions in an actual array.

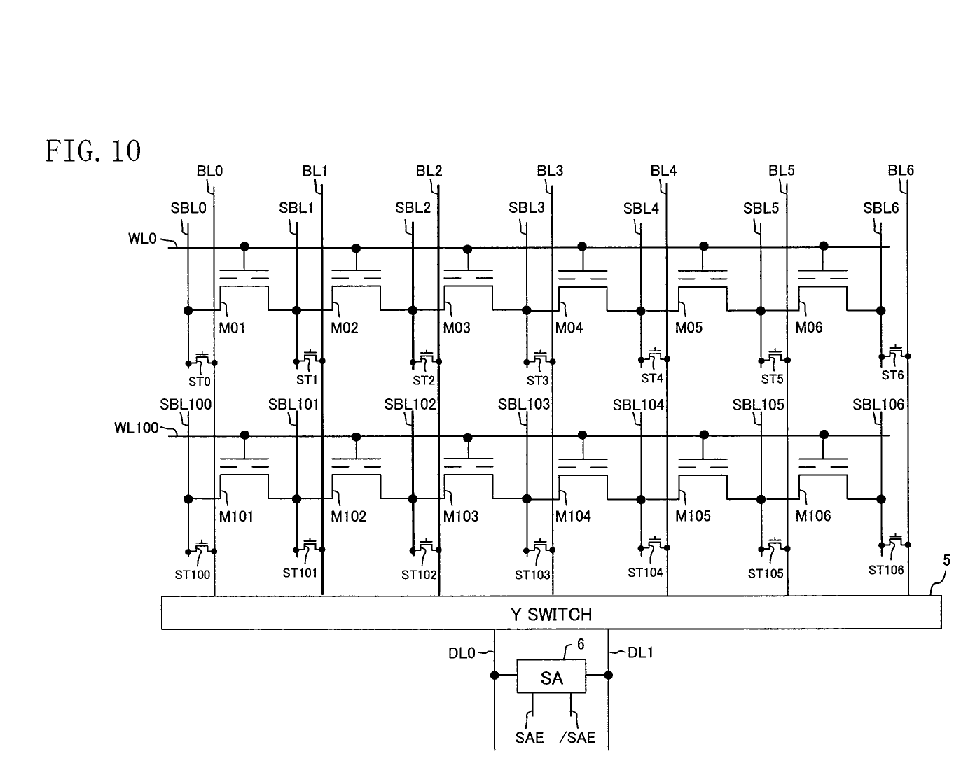

FIG. 10 is a diagram illustrating particular ones of the components shown in FIG. 9 which are necessary for describing this embodiment. Note that memory cells M101-M106, sub-bit lines SBL100-SBL106, selection transistors ST100-ST106, and a word line WL100 are equivalent to the memory cells M01-M06, the sub-bit lines BSL0-BSL06, the selection transistors ST0-ST6 and the word line WL0 shown in FIG. 9, respectively, although being identified by different reference characters.

A read operation according to the present disclosure will be described hereinafter with reference to FIG. 10, and advantages thereof will be clearly shown. In an initial state, the word lines WL0 and WL100 are at the Low level and are in a close state, and the bit lines BL0-BL6 and the sub-bit lines SBL0-SBL6 and SBL100-SBL106 are in a Hi-z state after having been precharged to the Low level. It is assumed that the Y switch 5 is an open state, so that the bit lines BL0-BL6 are not connected to the data lines DL0 and DL1, and also, the selection transistors ST0-ST6 and ST100-ST106 are all in an open state, so that the bit lines BL0-BL6 are not connected to the sub-bit lines SBL0-SBL6 and SBL100-SBL106.

First, the selection transistor ST1 is closed, so that the bit line BL1 is connected to the sub-bit line SBL1 connected to the drain of the memory cell M02 which is a target cell from which data is to be read. Also, the selection transistors ST2 and ST102 are closed, so that the sub-bit line SBL2 connected to the source of the memory cell M02 which is a target cell from which data is to be read is connected to the sub-bit line SBL102 via the bit line BL2 shared by the sub-bit lines SBL2 and SBL102. Next, after the bit line BL1 and the sub-bit line SBL1 are driven to the High level, the word line WL0 is caused to be at the High level, thereby reading data stored in the local charge portion of the memory cell M02 at the right hand side in FIG. 10. After a lapse of a certain time, the word line WL0 is caused to be at the Low level, and the selection transistor ST102 is opened to disconnect the sub-bit line SBL102 from the bit line BL2.

Next, the bit line BL1, the sub-bit line SBL1 and the sub-bit line SBL0 are returned to the Low level again to be in the Hi-z state. Thereafter, the selection transistor ST101 is closed to connect the sub-bit line SBL1 to the sub-bit line SBL101 via the bit line BL1 shared by the sub-bit lines SBL1 and SBL101. Next, the bit line BL2 and the sub-bit line SBL2 are caused to be at the High level, and the word line WL0 is caused to be at the High level, thereby reading data stored in the local charge portion of the memory cell M02 at the left hand side in FIG. 10. After a lapse of a certain time, the word line WL0 is caused to be at the Low level, and also, selection transistor ST101 is opened, thereby disconnecting the sub-bit line SBL101 from the bit line BL1. In this case, data stored in the memory cell M02 is retained in the form of potentials at the sub-bit lines SBL101 and SBL102.

Subsequently, potentials retained at the sub-bit lines are sent to the sense amplifier 6, and then, the operation is shifted to a data determination operation. First, the bit lines BL1 and BL2 are caused to be in the Hi-z state after being precharged to the Low state. At this time, the selection transistors ST1 and ST2 are in a close state, and thus, the sub-bit lines SBL1 and SBL2 are precharged to the Low state at the same time as the precharge of the bit lines BL1 and BL2. Next, the bit lines BL1 and BL2 are disconnected respectively from the sub-bit lines SBL1 and SBL2, and at the Y switch 5, the bit line BL1 is connected to the data line DL0 and the bit line BL2 is connected to the data line DL1. Next, the selection transistors ST101 and ST102 are closed to connect the sub-bit lines SB101 and SB102 respectively to the bit lines BL1 and BL2, the retained potentials are sent to the sense amplifier 6, and a difference between the potentials is amplified, thereby determining data.

By performing the above-described operation, similarly to the third embodiment, data in a complementally memory cell which could not be read at a time according to a known method can be read while increase in area due to an additional buffer (capacitors) is not caused. This embodiment shows that the present disclosure can be implemented even when a flash memory is not in the open array architecture of the third embodiment, and according to this embodiment, the degree of flexibility in array design is increased, so that the application area of the present disclosure can be increased.

Clearly, this embodiment can be realized in an open array architecture having a hierarchal bit line structure. The number of sub-bit lines for storing a single piece of data does not have to be one. The number of sub-bit lines for storing a single piece of data can be changed to optimize a capacitance for retaining data, the ratio between the capacitances of a sub-bit line and a bit line when a potential is transferred from the sub-bit line to a sense amplifier via the bit line, and the like.

### Fifth Embodiment

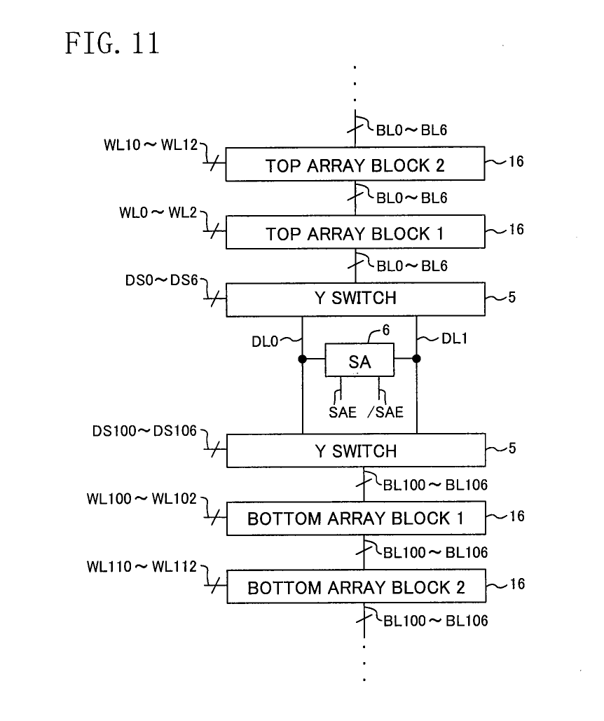

A fifth embodiment provides a solution to problems described in the first and second examples in the BACKGROUND section, and the solution is used when a flash memory has a hierarchical bit line structure. FIG. 11 is a diagram describing this embodiment. Note that the present disclosure is not limited to a solution method used when a flash memory has a hierarchical bit line structure.

FIG. 11 is a block diagram of a flash memory according to the fifth embodiment. The flash memory of FIG. 11 has an open array architecture in which a plurality of array blocks 16 and a Y switch 5 are provided both above and under (on the top and bottom of) a sense amplifier 6 as viewed in FIG. 11, and each block identified by the same reference character as that in FIG. 8 has the same internal configuration as that of FIG. 8. Note that an actual flash memory includes, in addition to the blocks shown in FIG. 11, various circuit blocks, but the description thereof is omitted. The block configuration of FIG. 11 and the example internal configurations of the blocks shown in FIGS. 9, 23, and 24 are merely illustrative examples, and the present disclosure is not limited to the configurations.

When data read from a memory cell in the array block 16 at the top side is retained at a bit line in the manner described as in the first embodiment or the third embodiment, a sub-bit line at which a potential is retained is switched using selection transistors in the manner as in the fourth embodiment. Thus, different pieces of data can be retained at a sub-bit line in the array block 16 at the bottom side and a sub-bit line in the array block 16 at the top side which does not include a memory cell from which data is read, so that the amount of data which can be retained at a time is increased. This is particularly useful when data is read from a plurality of memory cells at a time and then data is continuously output to the outside of the flash memory.

### Sixth Embodiment

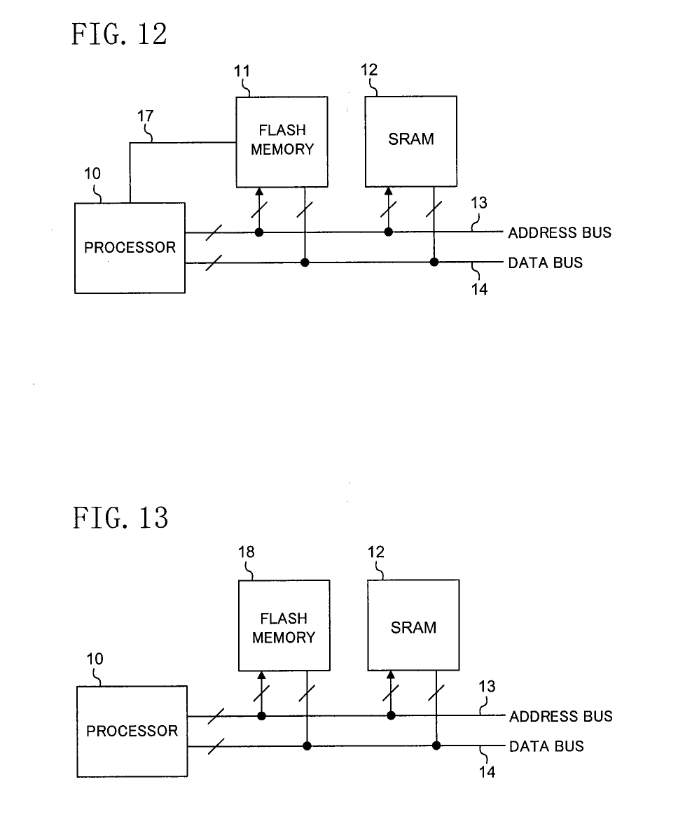

FIG. 12 is a configuration diagram of a computer system using a nonvolatile memory according to the present disclosure. The computer system of FIG. 12 includes a processor 10, a flash memory 11, and an SRAM 12. The processor 10, the flash memory 11 and the SRAM 12 are connected to one another via an address bus 13 and a data bus 14. The nonvolatile memory of the present disclosure is a semiconductor memory device using the techniques described in the first to fifth embodiments of the present disclosure. In the example of FIG. 12, the flash memory 11 corresponds to the nonvolatile memory, and the nonvolatile memory is connected to the processor 10 by a control signal line 17. Note that an actual computer system includes, in addition to the components shown in FIG. 12, various components such as a peripheral, an I/O port for performing communication with the peripheral, a control bus for performing control, and the like, which are necessary for the system. However, such components do not relate to the present disclosure, and therefore, the description thereof is omitted. The configuration shown in FIG. 12 is merely an example, and the present disclosure is not limited to the configuration.

In the techniques described in the first to fifth embodiments, electrical charges are stored at a capacitance of a bit line to temporarily store data. However, the amount of electrical charges stored at the bit line reduces with time due to leakage current and the like. When electrical charges reduce by a certain amount or more, data cannot be retained. That is, a temporary data retention time using a bit line capacitance is limited. Also, a method for exchanging data between the flash memory 11 and the processor 10 which is an external equipment is determined mainly by the processor 10, not by the flash memory 11. Normally, the flash memory 11 outputs data according to a request of the processor 10, and when the operation speed of the processor 10 is reduced in order to reduce power consumption, the data output speed of the flash memory 11 has to be reduced. This might cause a time required to temporarily retain data to exceed the limited temporary data retention time. To prevent such a situation, in this embodiment, a control signal is exchanged between the processor 10 and the flash memory 11 using the control signal line 17. Specifically, when the time required to temporarily retain data exceeds the limited temporary data retention time in the flash memory 11, the flash memory 11 sends a re-read request to the processor 10 via the control signal line 17 and, in response to the re-read request, the processor 10 sends a read order to the flash memory 11, thereby refreshing temporarily stored data in the flash memory 11.

In another example, when the time required to temporarily retain data exceeds the limited temporary data retention time in the flash memory 11, re-read is automatically executed in the flash memory 11. During the re-read, data cannot be output to the outside of the memory, and thus, a flag indicating that read preparation has not yet been done is sent to the processor 10 via the control signal line 17, thereby causing the processor 10 to wait to perform its operation.

By performing the above-described control, the techniques of the present disclosure described in the first to fifth embodiments can be used even when a timing condition for retaining data in the flash memory 11 is different from a timing condition for exchanging data with an external equipment at the outside of the flash memory 11.

### Seventh Embodiment

A seventh embodiment provides a solution to problems of the method in which write data is temporarily stored in a buffer to improve the write speed, which has been described in the third example in the BACKGROUND section. FIG. 11 is a diagram describing this embodiment. FIG. 11 is also used to describe the fifth embodiment. The seventh embodiment is similar to the fifth embodiment in that an actual flash memory includes, in addition to the blocks shown in FIG. 11, various circuit blocks, that the example block configuration and internal configuration are merely illustrative examples, and that the invention is not limited to the configurations.

A write operation according to the present disclosure will be described hereinafter with reference to FIG. 11, and advantages thereof will be clearly shown. In the fifth embodiment, a method for performing a read operation from a memory cell has been described. In contrast, in this embodiment, a method for performing a write operation to a memory cell will be described, and in this case, an example where data is written to a memory cell in an array block 16 at the top side will be described. First, data is input in the form of potential to a bit line in an array block at the bottom side from the outside of the flash memory. Although not shown in FIG. 11 because of space limitations, data lines DL0 and DL1 are connected to an equipment outside of the flash memory to drive the potential of the bit line to High or Low via a Y switch 5 at the bottom side, thereby performing the above-described data input. This data input can be performed in a several orders of magnitude shorter time than a time required for performing a write operation to a nonvolatile memory cell because this operation is performed by charging/discharging of electrical charges. As described in the fifth embodiment, when hierarchical bit lines are used, electrical charges are retained using sub-bit lines, so that the amount of write data which is to be temporarily stored can be increased. Thus, an even greater buffer effect can be achieved. It is also possible to retain data at a sub-bit line at the top side, but it is more preferable to use only a sub-bit line at the bottom side to retain write data because the operation method is simpler. In contrast, when data is written to a memory cell at the bottom side, it is preferable to use only a sub-bit line at the top side. After completing input from the outside, data (potential) retained at a sub-bit line is determined by a sense amplifier 6, and a bit line to be connected thereto by the Y switch 5 at the top side is driven, thereby performing data write to a memory cell of the array block 16 at the top side, which is a target memory cell to which data is written. If a long time is required for data write and the write time exceeds a time during which data can be retained at the sub-bit line, a sub-bit line potential is refreshed before data is lost.

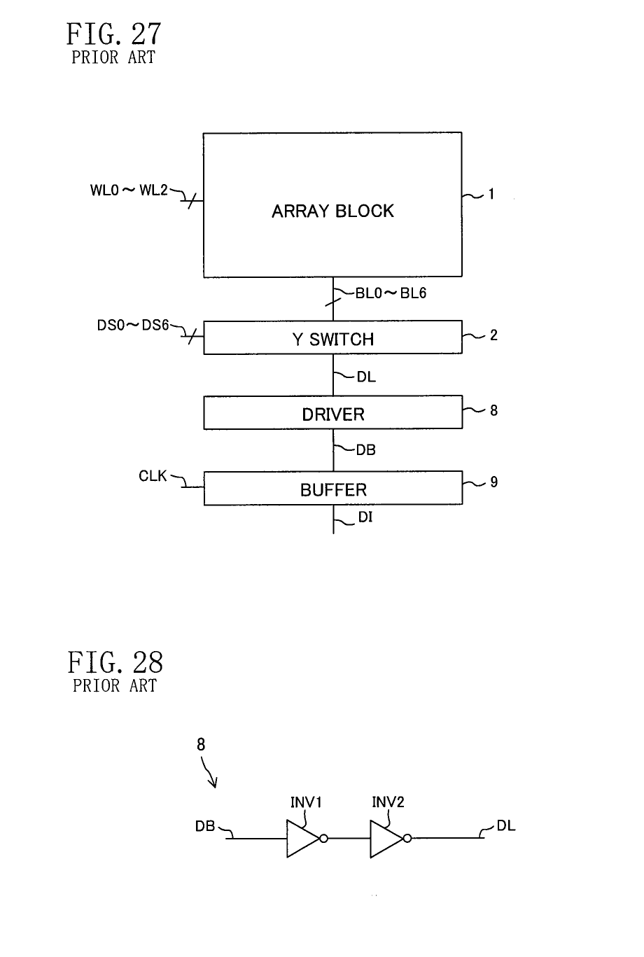

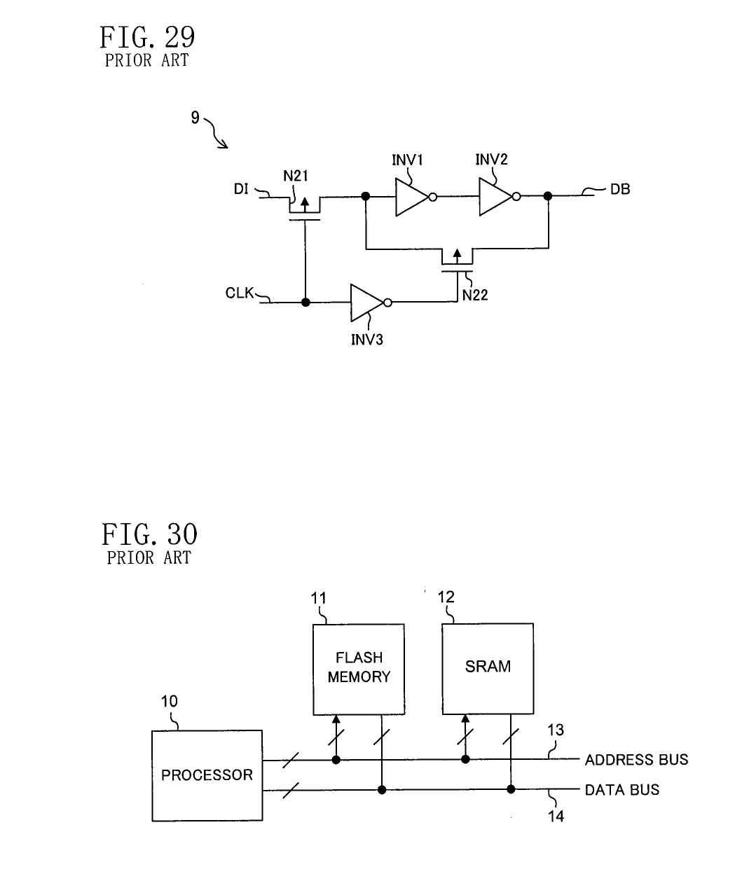

As described above, by using the present disclosure, write data can be input in a short time, and thereafter, there is no need to continuously apply data to the flash memory or perform like processing. Thus, a system using such a flash memory can perform another task, and therefore, the performance of the system can be improved. This means that the same advantages as those of the write buffer described in the third example in the BACKGROUND section are achieved. However, the buffer 9 of FIG. 27 is not provided as a component of the present disclosure, and thus, increase in a chip area because of the buffer 9 is not caused. Although it might seem that the array block 16 at the bottom side corresponds to the buffer 9, nonvolatile data can be stored in the array block 16 at the bottom side, and the array block 16 at the bottom side is not added as a buffer for temporarily storing read data. That is, the bit lines at the bottom side are components which exist even when a buffer is not used. Note that the block serving as the driver 8 in FIG. 27 serves as the sense amplifier 6 in FIG. 11. This is because the sense amplifier 6 is a type of sense amplifier for driving an input signal and can serve both as a differential amplifier and as a driver. Similar to the first embodiment, multiple ones of the configuration of FIG. 11 can be provided to simultaneously write data to a plurality of memory cells.

### Eighth Embodiment

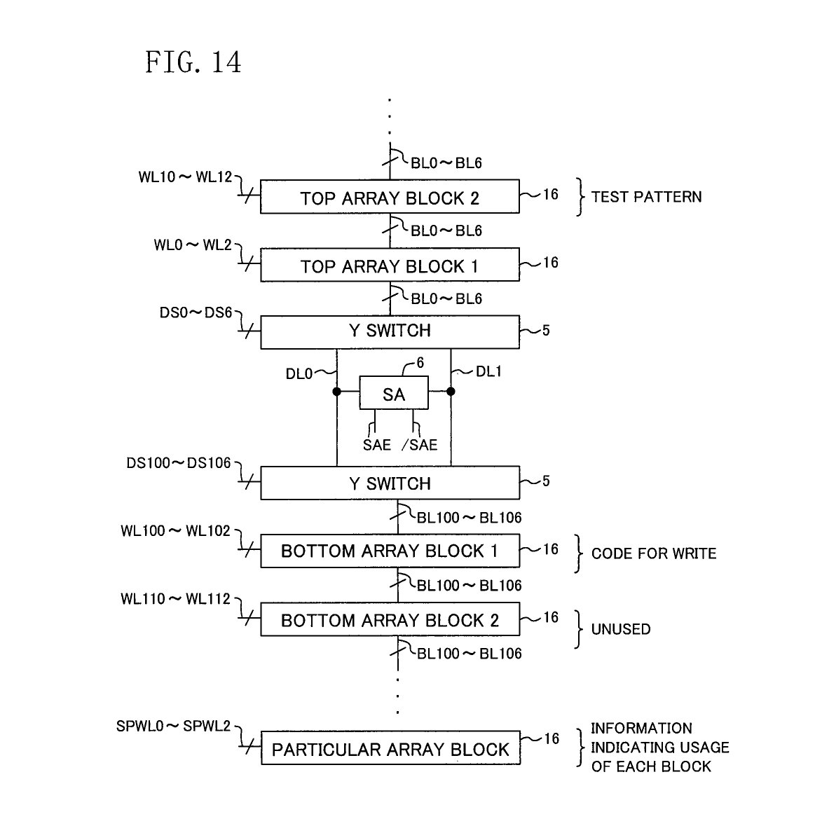

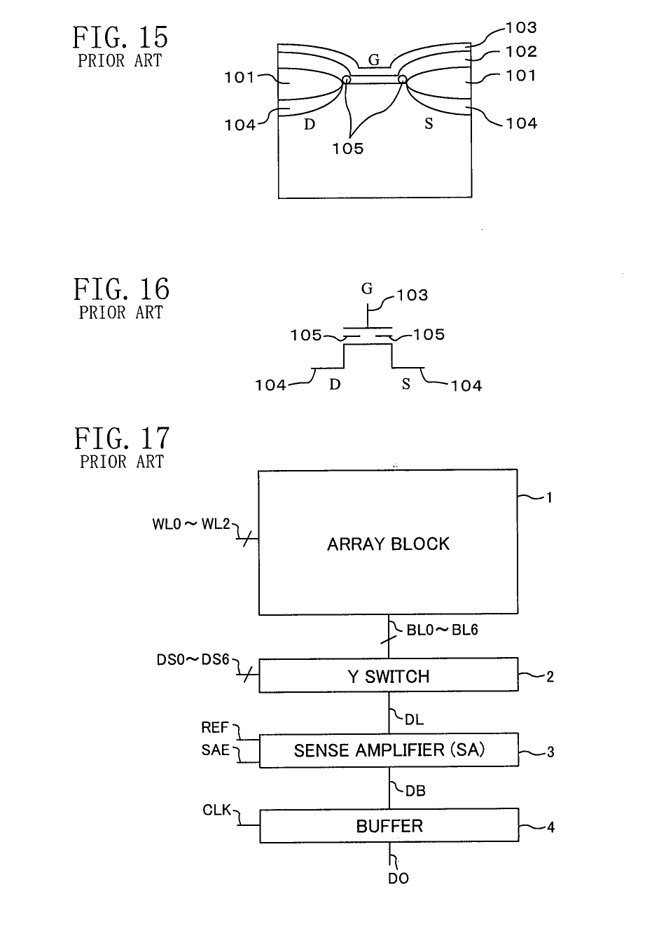

An eighth embodiment provides a solution to problems of the method described in the fourth example in the BACKGROUND section, for building a computer system using a flash memory. FIGS. 13 and 14 are diagrams describing this embodiment.

FIG. 13 is a configuration diagram of a computer system using a nonvolatile memory according to the present disclosure. The computer system includes a processor 10, a flash memory 18 and an SRAM 12. The processor 10, the flash memory 18 and the SRAM 12 are connected together via an address bus 13 and a data bus 14. The nonvolatile memory of the present disclosure is the flash memory 18 and, as shown in FIG. 14, a main structure thereof is an open array architecture in which a plurality of array blocks 16 and a Y switch 5 are provided both above and under (on the top and bottom of) a sense amplifier 6 as viewed in FIG. 14, and one of the array blocks 16 serves as a particular memory for recording a usage of each of the two array blocks 16.

Note that an actual computer system includes, in addition to the components shown in FIG. 13, various components, but the description of such components is omitted. The configuration shown in FIG. 13 is merely an example, and the present disclosure is not limited to the configuration. Similarly, the flash memory block configuration shown in FIG. 14 includes, in addition to the components shown in FIG. 14, various circuit blocks. The example block configuration and internal configuration are merely illustrative examples, and the invention is not limited to the configurations.

There are many cases where in a general method for using a flash memory, data for various applications exists in a single flash memory. As shown in FIG. 14, in the flash memory 18, in addition to a code to operate the processor 10, a code to operate a device for writing data to a flash memory, data to be used at a test, and an unused region exist. Other regions than a region of the code to operate the processor 10 are not used when the flash memory 18 is operated in the computer system shown in FIG. 13. According to the present disclosure, data is temporarily stored using a bit line of an array block in which data not to be used is stored, and thus, the flash memory 18 is operated also as a DRAM which is a volatile memory, not as a nonvolatile memory.

Specifically, a flag indicating what kind of data is stored in each array block (whether an array block is used or not when the flash memory 18 is operated in a computer system) is stored in a particular region of the flash memory 18. When the power of the computer system is turned on, the processor 10 reads data from the particular region first, and latches the data to a register or the like in the processor 10. Thereafter, the processor 10 adjusts allocation of addresses according to a value of the register. For example, in a region of the flash memory 18 in which data not to be used by the processor 10 is stored, an address of a RAM is newly allocated. At the flash memory 18 side, data is read from the above-described particular region when the power is turned on, and a region not to be used by the processor 10 is allocated to a region used as a DRAM, not as a flash memory. If an address indicating the region is output from the processor 10, write or read is performed to the region. Note that when this method is used, there might be cases where, after the power is turned on, a region to be used naturally as a DRAM exists. When read or write is performed to a nonvolatile memory in the region, a circuit design has to be devised. For example, an operation mode for the read or write is prepared, or an address allocated as the nonvolatile memory is input, so that the operation mode is automatically switched from a DRAM to a flash memory, and like.

The flash memory 18 can be used as a DRAM in simple manner by using the method described in the first or fifth embodiment as a read method, and the method described in the seventh embodiment as a write method, and also using the sense amplifier 6 as means for refreshing data. Note that it is also effective in the sixth and seventh embodiments to refresh data temporarily retained at a bit line using the sense amplifier 6.

As described above, a memory capacity which can be newly used as a RAM can be increased by effectively utilizing an unused region of the flash memory 18. Accordingly, the capacity of the SRAM 12 can be reduced and, if the capacity of a RAM which can be realized by the flash memory 18 satisfies a capacity required by the computer system, the SRAM 12 can be removed, and the number of components can be reduced. On the other hand, a region used as a DRAM of the flash memory 18 is a region necessary for causing the flash memory 18 to function, or a region which cannot be used for the user's convenience and the like, but is not a newly added region to increase the region of RAM. Thus, according to this embodiment, the chip area and the number of components, and the like are not increased.

According to the present disclosure, the usability of a nonvolatile memory as typified by a flash memory can be improved without increasing costs. As a result, low cost, high performance data storage equipment can be commercialized, and thus, is allowed to be used in the field of recording music and images, and the like.

In terms of application to a computer system, since an inventive memory device can be used not merely as a ROM but also as a RAM, and thus, a flexible computer system with high usability can be built by adjusting the capacities of the ROM and the RAM. Note that the computer system may be built as a computer system comprised of combination of system components such as a central processing unit (CPU), a ROM, a RAM and the like which are implemented as separate semiconductor products, or a computer system comprised of a single semiconductor product in which the above-described components are provided together. The present disclosure is useful in both of the computer systems.

What is claimed is:

1. A nonvolatile semiconductor memory device comprising:
a first memory cell;
a first bit line connected to the first memory cell to read data from the first memory cell;
a second memory cell;
a second bit line connected to the second memory cell to read data from the second memory cell;
a first data line;
a first switching device configured to connect the first data line to the first bit line; and
a second switching device configured to connect the first data line to the second bit line,
wherein data read from the first memory cell is retained by electrical charges stored at a capacitance of the second bit line.

2. The nonvolatile semiconductor memory device of claim 1, wherein
new data is read from the first memory cell to the first bit line simultaneously with outputting of the data retained at the second bit line.

3. The nonvolatile semiconductor memory device of claim 1, further comprising:
a first comparator; and
a third bit line,
wherein the second bit line and the third bit line are connected to an input of the first comparator.

4. The nonvolatile semiconductor memory device of claim 1, wherein
the first memory cell includes a plurality of local charge portions each being capable of storing static charges corresponding to data to be stored, and any two of the plurality of local charge portions store electrical charges in a complementary state.

5. The nonvolatile semiconductor memory device of claim 1, wherein
the second bit line has a hierarchical bit line structure, and data is retained by electrical charges stored at a capacitance of a sub-bit line of the second bit line.

6. The nonvolatile semiconductor memory device of claim 1, wherein
the second bit line has a hierarchical bit line structure, a plurality of sub-bit lines of the second bit line are provided, and a different piece of data is retained at each of the plurality of sub-bit lines.

7. The nonvolatile semiconductor memory device of claim 1, wherein
when an amount of electrical charges stored at the second bit line to retain data changes with time and it is difficult to retain the data, a signal indicating that the data stored at the second bit line is lost is output.

8. An electronic equipment, comprising:
the nonvolatile semiconductor memory device of claim 7; and
a control device configured to receive a signal output from the semiconductor memory device and instruct the semiconductor memory device to perform an operation according to the signal.

9. The nonvolatile semiconductor memory device of claim 1, wherein
when an amount of electrical charges stored at the second bit line to retain data changes with time and it is difficult to retain the data, data read from the first memory cell is executed again and a signal indicating that re-read is being executed is output.

10. An electronic equipment, comprising:
the nonvolatile semiconductor memory device of claim 9; and
a device configured to receive a signal output from the semiconductor memory device and control an operation instruction to the semiconductor memory device according to the signal.

11. A nonvolatile semiconductor memory device comprising:
a first memory cell;
a first bit line connected to the first memory cell to read data from the first memory cell;
a first switching device;
a second bit line configured to be connected to the first bit line via the first switching device; and
a second memory cell connected to the second bit line, wherein
other data than read or write data of the first memory cell is retained by electrical charges stored at a capacitance of the second bit line, and
a nonvolatile data is not stored in the second memory cell.

12. An electronic equipment, comprising:
the nonvolatile semiconductor memory device of claim 11; and
a control device configured to change an address to be allocated to the second memory cell provided in the semiconductor memory device.

13. A nonvolatile semiconductor memory device comprising:
a first memory cell;
a first bit line connected to the first memory cell to read data from the first memory cell;
a first switching device;
a second bit line configured to be connected to the first bit line via the first switching device; and
a second memory cell connected to the second bit line, wherein
other data than read or write data of the first memory cell is retained by electrical charges stored at a capacitance of the second bit line, and
a nonvolatile data stored in the second memory cell is not used.

14. An electronic equipment, comprising:
the nonvolatile semiconductor memory device of claim 13; and
a control device configured to change an address to be allocated to the second memory cell provided in the semiconductor memory device.

15. The nonvolatile semiconductor memory device of claim 1, wherein
before an amount of electrical charges stored at the second bit line to retain data changes with time and it is difficult to retain the data, the amount of electrical charges stored at the second bit line is amplified.
